(19) United States
(12) Patent Application Publication
(10) Pub. No.: US 2021/0408059 A1
(43) Pub. Date: Dec. 30, 2021

(54) FAN-OUT WIRE STRUCTURE, DISPLAY PANEL, AND DISPLAY DEVICE

(71) Applicant: WUHAN CHINA STAR OPTOELECTRONICS TECHNOLOGY CO., LTD., WUHAN, HUBEI (CN)

(72) Inventors: Zhihao CAO, Wuhan, Hubei (CN); Wei TANG, Wuhan, Hubei (CN)

(21) Appl. No.: 17/042,136

(22) PCT Filed: Jul. 23, 2020
(86) PCT No.: PCT/CN2020/103882

§ 371 Date: Sep. 27, 2020

(30) Foreign Application Priority Data
Jun. 28, 2020 (CN) 2020106009452

(51) Int. Cl. H01L 27/12; H01L 49/02

(52) U.S. Cl. CPC H01L 27/124; H01L 27/1255; H01L 28/20

(57) ABSTRACT

A fan-out wire structure, a display panel, and a display device are provided. The fan-out wire structure includes a first wiring layer, a second wiring layer, and a plurality of fan-out wires. The fan-out wires include a plurality of first fan-out wires and a plurality of second fan-out wires. The first fan-out wires are disposed in the first wiring layer. The fan-out wires are disposed in the second wiring layer. Each of the first fan-out wires is provided with a first impedance unit. Each of the second fan-out wires is provided with a second impedance unit.

### FIELD OF INVENTION

The present disclosure relates to the technical field of display, and particularly to a fan-out wire structure, a display panel, and a display device.

### BACKGROUND

In the display field of low-temperature poly-silicon (LTPS) technology, because the LTPS technology has advantages of high aperture ratio and high resolution, more medium-sized and even large-sized display panels tend to use the LTPS technology.

However, medium-sized and large-sized display panels require high impedance uniformity of data traces, especially for large-sized display panels. In the era of high resolution, a conventional fan-out single-layer metal wiring can no longer meet requirements of data traces. Generally, in designs of small-sized and medium-sized display panels, a single layer of metal is used. Because a display panel has a small size, an impedance difference between different positions of the display panel is very small and within an acceptable range. However, as the display panel becomes larger, as shown in FIG. 1, a distance at diagonal lines 11 also increases. And, as a resolution of the display panel increases, a number of data traces required in a same space also increases. Design of a fan-out area of large-sized and high-resolution products is limited and needs to be optimized and improved.

Therefore, how to reduce impacts of an increase in size and resolution of a display panel on impedance uniformity of data traces and optimize a fan-out wire structure has become a technical problem to be solved urgently by those skilled in the art and a focus of research.

### SUMMARY OF DISCLOSURE

In view of this, the present disclosure provides a fan-out wire structure, a display panel, and a display device to solve the problem of decrease in impedance uniformity of data traces due to an increase in size and resolution of the display panel.

Accordingly, the present disclosure provides the following technical solutions.

In a first aspect, the present disclosure provides a fan-out wire structure comprising a first wiring layer, a second wiring layer, and a plurality of fan-out wires. The first wiring layer and the second wiring layer are disposed in parallel. The fan-out wires comprise a plurality of first fan-out wires and a plurality of second fan-out wires. The first fan-out wires are disposed in the first wiring layer. The second fan-out wires are disposed in the second wiring layer. Each of the first fan-out wires is provided with a first impedance unit. Each of the second fan-out wires is provided with a second impedance unit. Each of the first impedance units is provided with a first ion implantation area for being implanted with ions to change a resistance of the first impedance unit. Each of the second impedance units is provided with a second ion implantation area for being implanted with the ions to change a resistance of the second impedance unit.

In an embodiment, each of the first impedance units comprises a first polysilicon resistor, and each of the second impedance units comprises a second polysilicon resistor. A volume of each of the first polysilicon resistors decreases as a length of a corresponding first fan-out wire increases. A volume of each of the second polysilicon resistors decreases as a length of a corresponding second fan-out wire increases.

In an embodiment, each of the first impedance units comprises a third polysilicon resistor, and each of the second impedance units comprises a fourth polysilicon resistor. An amount of polysilicon implanted in each of the third polysilicon resistors decreases as a length of a corresponding first fan-out wire increases. An amount of polysilicon implanted in each of the fourth polysilicon resistors decreases as a length of a corresponding second fan-out wire increases.

In an embodiment, the ions are N-type ions and/or P-type ions.

In an embodiment, a size of the first ion implantation areas is determined according to a thickness of the first wiring layer, and a size of the second ion implantation areas is determined according to a thickness of the second wiring layer.

In a second aspect, the present disclosure further provides a display panel comprising a substrate, a plurality of scan lines, a driving circuit, and a fan-out wire structure. The scan lines are disposed in a display area of the substrate. The driving circuit is configured to drive the scan lines. The fan-out wire structure is disposed between the driving circuit and the scan lines. The fan-out wire structure comprises a first wiring layer, a second wiring layer, and a plurality of fan-out wires. The first wiring layer and the second wiring layer are disposed in parallel. The fan-out wires comprise a plurality of first fan-out wires and a plurality of second fan-out wires. The first fan-out wires are disposed in the first wiring layer. The second fan-out wires are disposed in the second wiring layer. Each of the first fan-out wires is provided with a first impedance unit. Each of the second fan-out wires is provided with a second impedance unit. Each of the first impedance units is provided with a first ion implantation area for being implanted with ions to change a resistance of the first impedance unit. Each of the second impedance units is provided with a second ion implantation area for being implanted with the ions to change a resistance of the second impedance unit.

In an embodiment, each of the first impedance units comprises a first polysilicon resistor, and each of the second impedance units comprises a second polysilicon resistor. A volume of each of the first polysilicon resistors decreases as a length of a corresponding first fan-out wire increases. A volume of each of the second polysilicon resistors decreases as a length of a corresponding second fan-out wire increases.

In an embodiment, each of the first impedance units comprises a third polysilicon resistor, and each of the second impedance units comprises a fourth polysilicon resistor. An amount of polysilicon implanted in each of the third polysilicon resistors decreases as a length of a corresponding first fan-out wire increases. An amount of polysilicon implanted in each of the fourth polysilicon resistors decreases as a length of a corresponding second fan-out wire increases.

In an embodiment, the ions are N-type ions and/or P-type ions.

In a third aspect, the present disclosure further provides a display device comprising the display panel according to any one of the embodiments of the third aspect of the present disclosure.

The present disclosure provides a fan-out wire structure, which adopts double-layer wiring to meet requirements of data traces of a large-sized and high-resolution display panel. By disposing impedance units on the fan-out wires, an impedance difference between the fan-out wires can be balanced. By disposing different ion implantation areas on the impedance units in different wiring layers, the impedance difference between the fan-out wires can be balanced.

### BRIEF DESCRIPTION OF DRAWINGS

In order to more clearly illustrate technical solutions in specific embodiments of the present disclosure and the prior art, a brief description of accompanying drawings used in descriptions of the specific embodiments and the prior art will be given below. Obviously, the accompanying drawings in the following description are merely some embodiments of the present disclosure. For those skilled in the art, other drawings may be obtained from these accompanying drawings without creative labor.

FIG. 1 is a schematic diagram of a fan-out wire structure in the prior art.

FIG. 2 is a schematic diagram of a fan-out wire structure according to an embodiment of the present disclosure.

### DETAILED DESCRIPTION

Technical solutions in embodiments of the present disclosure will be clearly and completely described below in conjunction with accompanying drawings in the embodiments of the present disclosure. Apparently, the described embodiments are merely some of the embodiments of the present disclosure and not all embodiments. All other embodiments obtained by those skilled in the art based on the embodiments of the present disclosure without creative labor are within the claimed scope of the present invention.

In the description of the present disclosure, it should be understood that location or position relationships indicated by terms, such as “center”, “longitudinal”, “transverse”, “length”, “width”, “thickness”, “up”, “down”, “front”, “rear”, “left”, “right”, “vertical”, “horizontal”, “top”, “bottom”, “within”, “outside”, “clockwise”, and “counterclockwise” are location or position relationships based on illustration of the accompanying drawings, are merely used for describing the present disclosure and simplifying the description instead of indicating or implying the indicated apparatuses or elements should have specified locations or be constructed and operated according to specified locations, and Thereof, should not be intercepted as limitations to the present disclosure. Furthermore, terms such as “first” and “second” are used merely for description, but shall not be construed as indicating or implying relative importance or implicitly indicating a number of the indicated technical feature. Hence, the feature defined with “first” and “second” may explicitly or implicitly includes one or more such features. In the description of the present disclosure, a term “a plurality of” means “two or more” unless otherwise specifically limited.

In the present disclosure, it should be noted that, unless otherwise explicitly specified or defined, the terms such as “mount”, “connect”, and “connection” should be interpreted in a broad sense. For example, a connection may be a fixed connection, a detachable connection, or an integral connection. A connection may be a mechanical connection, an electrical connection, or a mutual communication. A connection may be a direct connection or may be an indirect connection by using an intermediate medium. A connection may be an internal connection or an interaction between two elements. It may be appreciated by those of ordinary skill in the art that the specific meanings of the aforementioned terms in the present disclosure can be understood depending on specific situations.

n the present disclosure, unless otherwise specifically specified or limited, a structure in which a first feature is “on” or “under” a second feature may comprise an embodiment in which the first feature directly contacts the second feature, and may also comprise an embodiment in which the first feature and the second feature are not in direct contact with each other, but are contacted via an additional feature formed therebetween. Furthermore, a structure in which a first feature is “on”, “above”, or “on top of” a second feature may comprise an embodiment in which the first feature is right or obliquely “on”, “above”, or “on top of” the second feature, or just means that a sea-level elevation of the first feature is greater than a sea-level elevation of the second feature. A structure in which a first feature “under”, “below”, or “on bottom of” a second feature may include an embodiment in which the first feature is right “beneath,” “below,” or “on bottom of” the second feature, and may also comprises an embodiment in which the first feature is right or obliquely “under”, “below”, or “on bottom of” the second feature, or just means that a sea-level elevation of the first feature is less than a sea-level elevation of the second feature.

The following description provides different embodiments or examples illustrating various structures of the present invention. In order to simplify the description of the present disclosure, only components and settings of specific examples are described below. They are only examples and are not intended to limit the present invention. Furthermore, reference numerals and/or letters may be repeated in different examples of the present disclosure. Such repetitions are for simplicity and clarity, which per se do not indicate relations among the discussed embodiments and/or settings. Furthermore, the present disclosure provides various examples of specific processes and materials, but those skilled in the art can be aware of application of other processes and/or use of other materials.

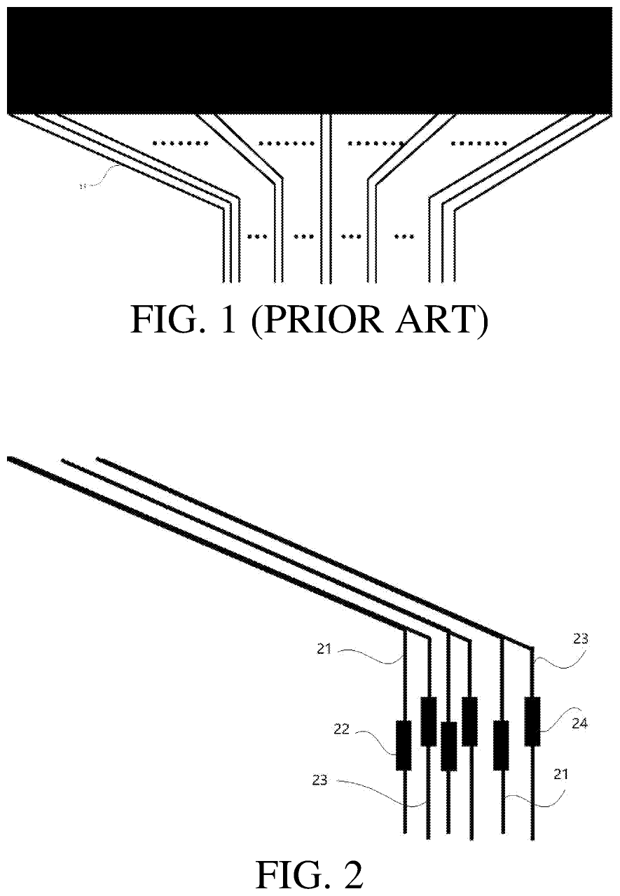

FIG. 1 is a schematic diagram of a fan-out wire structure in the prior art. As shown in FIG. 1, as a size of a display panel increases, a distance at diagonal lines 11 increases, and a length difference between different fan-out wires increases. This easily leads to uneven impedances of the fan-out wires, resulting in signal distortion. The longer the fan-out wires, the more serious the signal distortion, which affects display effect of the display panel.

FIG. 2 is a schematic diagram of a fan-out wire structure according to an embodiment of the present disclosure. As shown in FIG. 2, the present disclosure provides a fan-out wire structure comprising a first wiring layer, a second wiring layer, and a plurality of fan-out wires. The first wiring layer and the second wiring layer are disposed in parallel. The fan-out wires comprise a plurality of first fan-out wires 21 and a plurality of second fan-out wires 23. The first fan-out wires 21 are disposed in the first wiring layer. The second fan-out wires 23 are disposed in the second wiring layer. Each of the first fan-out wires 21 is provided with a first impedance unit 22. Each of the second fan-out wires 23 is provided with a second impedance unit 24. Each of the first impedance units 22 is provided with a first ion implantation area for being implanted with ions to change a resistance of the first impedance unit 22. Each of the second impedance units 24 is provided with a second ion implantation area for being implanted with the ions to change a resistance of the second impedance unit 24.

In this embodiment, the first wiring layer and the second wiring layer are conductive layers. An insulating layer is disposed between the first wiring layer and the second wiring layer. The first impedance units 22 and the second impedance units 24 are configured to balance impedances of the fan-out wires. When the impedances are different due to a difference in thickness and/or material of the first wiring layer and the second wiring layer, the impedances can be adjusted by adjusting sizes of the first ion implantation areas and the second ion implantation areas to achieve impedance uniformity. When the first wiring layer and/or the second wiring layer are changed due to manufacturing requirements, the impedances can be adjusted by adjusting the sizes of the first ion implantation areas and the second ion implantation areas, so as to achieve impedance uniformity. The first impedance units 22 and the second impedance units 24 are preferably disposed alternately. The first fan-out wires 21 and the second fan-out wires 23 have a same wiring shape and are disposed in parallel.

Compared with the prior art, the present disclosure provides a fan-out wire structure, which adopts double-layer metal wiring design. This is beneficial to save space and can meet requirements of data traces of a large-sized and high-resolution display panel. By disposing impedance units on fan-out wires, an impedance difference between the fan-out wires can be balanced. By disposing different ion implantation areas on the impedance units in different wiring layers, the impedance difference between the fan-out wires can be balanced. This is beneficial to improve impedance uniformity of the fan-out wires.

In a specific embodiment, each of the first impedance units comprises a first polysilicon resistor, and each of the second impedance units comprises a second polysilicon resistor. A volume of each of the first polysilicon resistors decreases as a length of a corresponding first fan-out wire increases. A volume of each of the second polysilicon resistors decreases as a length of a corresponding second fan-out wire increases.

In this embodiment, resistance values of the first polysilicon resistors and the second polysilicon resistors may be adjusted by adjusting the volumes of the first polysilicon resistors and the second polysilicon resistors. Adjusting the resistance values of the first polysilicon resistors according to the lengths of the first fan-out wires and adjusting the resistance values of the second polysilicon resistors according to the lengths of the second fan-out wires can balance impedance difference caused by different lengths of the fan-out wires.

In a specific embodiment, each of the first impedance units comprises a third polysilicon resistor, and each of the second impedance units comprises a fourth polysilicon resistor. An amount of polysilicon implanted in each of the third polysilicon resistors decreases as a length of a corresponding first fan-out wire increases. An amount of polysilicon implanted in each of the fourth polysilicon resistors decreases as a length of a corresponding second fan-out wire increases.

In this embodiment, resistance values of the first polysilicon resistors and the second polysilicon resistors may be adjusted by adjusting the amounts of polysilicon implanted in the third polysilicon resistors and the fourth polysilicon resistors. Adjusting the resistance values of the first polysilicon resistors according to the lengths of the first fan-out wires and adjusting the resistance values of the second polysilicon resistors according to the lengths of the second fan-out wires can balance the impedance difference caused by the different lengths of the fan-out wires.

In an alternative embodiment, the third polysilicon resistors may be the first polysilicon resistors, and the fourth polysilicon resistors may be the second polysilicon resistors.

In a specific embodiment, the ions are N-type ions and/or P-type ions. Those skilled in the art should know that the ions may be, but are not limited to, the aforementioned N-type ions and P-type ions, and may also be other ions that can adjust the resistance values.

In this embodiment, the resistance values may be increased by implanting opposite types of ions into doped regions of the first impedance units and the second impedance units.

In a specific embodiment, a size of the first ion implantation areas is determined according to a thickness of the first wiring layer, and a size of the second ion implantation areas is determined according to a thickness of the second wiring layer.

In this embodiment, determining the sizes of the ion implantation areas according to the thicknesses of the first and second wiring layers can balance impedance difference due to materials of the wiring layers. This is beneficial to improve the impedance uniformity of the fan-out wires.

The present disclosure further provides a display panel comprising a substrate, a plurality of scan lines, a driving circuit, and a fan-out wire structure. The scan lines are disposed in a display area of the substrate. The driving circuit is configured to drive the scan lines. The fan-out wire structure is disposed between the driving circuit and the scan lines. The fan-out wire structure comprises a first wiring layer, a second wiring layer, and a plurality of fan-out wires. The first wiring layer and the second wiring layer are disposed in parallel. The fan-out wires comprise a plurality of first fan-out wires and a plurality of second fan-out wires. The first fan-out wires are disposed in the first wiring layer. The second fan-out wires are disposed in the second wiring layer. Each of the first fan-out wires is provided with a first impedance unit. Each of the second fan-out wires is provided with a second impedance unit. Each of the first impedance units is provided with a first ion implantation area for being implanted with ions to change a resistance of the first impedance unit. Each of the second impedance units is provided with a second ion implantation area for being implanted with the ions to change a resistance of the second impedance unit.

Compared with the prior art, the present disclosure provides a display panel comprising a fan-out wire structure that adopts double-layer metal wiring design. This is beneficial to save space and can meet requirements of data traces of a large-sized and high-resolution display panel. By disposing impedance units on fan-out wires, an impedance difference between the fan-out wires can be balanced. By disposing different ion implantation areas on the impedance units in different wiring layers, the impedance difference between the fan-out wires can be balanced. This is beneficial to improve impedance uniformity of the fan-out wires.

In a specific embodiment, each of the first impedance units comprises a first polysilicon resistor, and each of the second impedance units comprises a second polysilicon resistor. A volume of each of the first polysilicon resistors decreases as a length of a corresponding first fan-out wire increases. A volume of each of the second polysilicon resistors decreases as a length of a corresponding second fan-out wire increases.

In this embodiment, resistance values of the first polysilicon resistors and the second polysilicon resistors may be adjusted by adjusting the volumes of the first polysilicon resistors and the second polysilicon resistors. Adjusting the resistance values of the first polysilicon resistors according to the lengths of the first fan-out wires and adjusting the resistance values of the second polysilicon resistors according to the lengths of the second fan-out wires can balance impedance difference caused by different lengths of the fan-out wires.

In a specific embodiment, each of the first impedance units comprises a third polysilicon resistor, and each of the second impedance units comprises a fourth polysilicon resistor. An amount of polysilicon implanted in each of the third polysilicon resistors decreases as a length of a corresponding first fan-out wire increases. An amount of polysilicon implanted in each of the fourth polysilicon resistors decreases as a length of a corresponding second fan-out wire increases.

In this embodiment, resistance values of the first polysilicon resistors and the second polysilicon resistors may be adjusted by adjusting the amounts of polysilicon implanted in the third polysilicon resistors and the fourth polysilicon resistors. Adjusting the resistance values of the first polysilicon resistors according to the lengths of the first fan-out wires and adjusting the resistance values of the second polysilicon resistors according to the lengths of the second fan-out wires can balance the impedance difference caused by the different lengths of the fan-out wires.

In a specific embodiment, the ions are N-type ions and/or P-type ions.

In this embodiment, the resistance values may be increased by implanting opposite types of ions into doped regions of the first impedance units and the second impedance units.

The present disclosure further provides a display device comprising the display panel according to any one of the above embodiments.

The embodiments of the present invention have been described in conjunction with the accompanying drawings, but those skilled in the art may make various changes and modifications without departing from the scope of the present invention, and such changes and modifications fall within the scope of the appended claims.

The present disclosure provides a fan-out wire structure, a display panel, and a display device. Because the low-temperature poly-silicon (LTPS) technology has advantages of high aperture ratio and high resolution, more medium-sized and even large-sized display panels tend to use the LTPS technology. However, medium-sized and large-sized display panels require high impedance uniformity of data traces, especially large-sized display panels. In the era of high resolution, a conventional fan-out single-layer metal wiring can no longer meet requirements of data traces. In the present invention, an impedance difference between the fan-out wires can be balanced by disposing impedance units on the fan-out wires and by disposing different ion implantation areas on the impedance units in different wiring layers.

1. A fan-out wire structure, comprising:
a first wiring layer;
a second wiring layer disposed in parallel with the first wiring layer; and
a plurality of fan-out wires comprising:
a plurality of first fan-out wires disposed in the first wiring layer, wherein each of the first fan-out wires is provided with a first impedance unit, and each of the first impedance units is provided with a first ion implantation area for being implanted with ions to change a resistance of the first impedance unit; and
a plurality of second fan-out wires disposed in the second wiring layer, wherein each of the second fan-out wires is provided with a second impedance unit, and each of the second impedance units is provided with a second ion implantation area for being implanted with the ions to change a resistance of the second impedance unit.

2. The fan-out wire structure according to claim 1, wherein
each of the first impedance units comprises a first polysilicon resistor, wherein a volume of each of the first polysilicon resistors decreases as a length of a corresponding first fan-out wire increases; and
each of the second impedance units comprises a second polysilicon resistor, wherein a volume of each of the second polysilicon resistors decreases as a length of a corresponding second fan-out wire increases.

3. The fan-out wire structure according to claim 1, wherein
each of the first impedance units comprises a third polysilicon resistor, wherein an amount of polysilicon implanted in each of the third polysilicon resistors decreases as a length of a corresponding first fan-out wire increases; and
each of the second impedance units comprises a fourth polysilicon resistor, wherein an amount of polysilicon implanted in each of the fourth polysilicon resistors decreases as a length of a corresponding second fan-out wire increases.

4. The fan-out wire structure according to claim 1, wherein the ions are N-type ions or P-type ions.

5. The fan-out wire structure according to claim 1, wherein a size of the first ion implantation areas is determined according to a thickness of the first wiring layer, and a size of the second ion implantation areas is determined according to a thickness of the second wiring layer.

6. A display panel, comprising:
a substrate comprising a display area;
a plurality of scan lines disposed in the display area of the substrate;
a driving circuit configured to drive the scan lines; and
a fan-out wire structure disposed between the driving circuit and the scan lines and comprising:
a first wiring layer;
a second wiring layer disposed in parallel with the first wiring layer; and
a plurality of fan-out wires comprising:
a plurality of first fan-out wires disposed in the first wiring layer, wherein each of the first fan-out wires is provided with a first impedance unit, and each of the first impedance units is provided with a first ion implantation area for being implanted with ions to change a resistance of the first impedance unit; and
a plurality of second fan-out wires disposed in the second wiring layer, wherein each of the second fan-out wires is provided with a second impedance unit, and each of the second impedance units is provided with a second ion implantation area for being implanted with the ions to change a resistance of the second impedance unit.

7. The display panel according to claim 6, wherein
each of the first impedance units comprises a first polysilicon resistor, wherein a volume of each of the first polysilicon resistors decreases as a length of a corresponding first fan-out wire increases; and
each of the second impedance units comprises a second polysilicon resistor, wherein a volume of each of the second polysilicon resistors decreases as a length of a corresponding second fan-out wire increases.

8. The display panel according to claim 6, wherein
each of the first impedance units comprises a third polysilicon resistor, wherein an amount of polysilicon implanted in each of the third polysilicon resistors decreases as a length of a corresponding first fan-out wire increases; and
each of the second impedance units comprises a fourth polysilicon resistor, wherein an amount of polysilicon implanted in each of the fourth polysilicon resistors decreases as a length of a corresponding second fan-out wire increases.

9. The display panel according to claim 6, wherein the ions are N-type ions or P-type ions.

10. A display device, comprising a display panel, wherein the display panel comprises:
a substrate comprising a display area;
a plurality of scan lines disposed in the display area of the substrate;
a driving circuit configured to drive the scan lines; and
a fan-out wire structure disposed between the driving circuit and the scan lines and comprising:
a first wiring layer;
a second wiring layer disposed in parallel with the first wiring layer; and
a plurality of fan-out wires comprising:
a plurality of first fan-out wires disposed in the first wiring layer, wherein each of the first fan-out wires is provided with a first impedance unit, and each of the first impedance units is provided with a first ion implantation area for being implanted with ions to change a resistance of the first impedance unit; and
a plurality of second fan-out wires disposed in the second wiring layer, wherein each of the second fan-out wires is provided with a second impedance unit, and each of the second impedance units is provided with a second ion implantation area for being implanted with the ions to change a resistance of the second impedance unit.

11. The display device according to claim 10, wherein
each of the first impedance units comprises a first polysilicon resistor, wherein a volume of each of the first polysilicon resistors decreases as a length of a corresponding first fan-out wire increases; and
each of the second impedance units comprises a second polysilicon resistor, wherein a volume of each of the second polysilicon resistors decreases as a length of a corresponding second fan-out wire increases.

12. The display device according to claim 10, wherein
each of the first impedance units comprises a third polysilicon resistor, wherein an amount of polysilicon implanted in each of the third polysilicon resistors decreases as a length of a corresponding first fan-out wire increases; and
each of the second impedance units comprises a fourth polysilicon resistor, wherein an amount of polysilicon implanted in each of the fourth polysilicon resistors decreases as a length of a corresponding second fan-out wire increases.

13. The display device according to claim 10, wherein the ions are N-type ions or P-type ions.
